(19) United States
(12) Patent Application Publication
(10) Pub. No.: US 2026/0153804 A1
(43) Pub. Date: Jun. 4, 2026

(54) PHOTOSENSITIVE RESIN FILM, PRINTED WIRING BOARD, AND SEMICONDUCTOR PACKAGE

(71) Applicant: Resonac Corporation, Minato-ku, Tokyo (JP)

(72) Inventors: Kohei ABE, Minato-ku, Tokyo (JP); Ryo YUKIOKA, Minato-ku, Tokyo (JP); Takeshi NOJIRI, Minato-ku, Tokyo (JP); Masahiro MIYASAKA, Minato-ku, Tokyo (JP); Hayato SAWAMOTO, Minato-ku, Tokyo (JP)

(21) Appl. No.: 18/855,850

(22) PCT Filed: Apr. 3, 2024
(86) PCT No.: PCT/JP2024/013720

§ 371 Date: Oct. 10, 2024

(30) Foreign Application Priority Data
Apr. 6, 2023 (JP) 2023-061898

(51) Int. Cl. G03F 7/038; C08K 7/18; H05K 1/03

(52) U.S. Cl. CPC G03F 7/0382; C08K 7/18; H05K 1/0353; H05K 2201/0209; H05K 2201/0218; H05K 2201/0242

(57) ABSTRACT

A photosensitive resin film containing (A) a photopolymerizable compound having an ethylenically unsaturated group and an acidic substituent and (B) an inorganic filler, in which the amount of the inorganic filler (B) contained is 25% by volume or more, and in which the cured product of the photosensitive resin film has a refractive index of 1.550 or more, and a printed wiring board and a semiconductor package each using the photosensitive resin film.

### TECHNICAL FIELD

The present disclosure relates to a photosensitive resin film, a printed wiring board, and a semiconductor package.

### BACKGROUND ART

In recent years, electronic devices are increasingly reduced in size and improved in performance, and the printed wiring boards used in such devices are being increased in density as the number of circuit layers is increased and the wirings are scaled down. Particularly, the increase of density is marked in semiconductor package substrates on which a semiconductor chip is to be mounted, such as ball grid array (BGA) and chip size package (CSP), and the semiconductor package substrates require reduction of the thickness of an insulating layer and further reduction of the diameter of a via (referred to also as “via hole”) for interlayer connection as well as shrinking the wirings.

Examples of the methods for producing a printed wiring board, which have been conventionally employed, include a method for producing a printed wiring board by a build-up process in which an interlayer insulating layer and a conductor circuit layer are successively laminated on one another (see, for example, PTL 1). As the wirings shrink, a printed wiring board is mainly produced by a semi-additive process in which a circuit is formed by plating.

In the conventional semi-additive process, for example, (1) a thermosetting resin film is laminated on a conductor circuit, and then the thermosetting resin film is cured by heating to form an “interlayer insulating layer”. (2) Then, a via for interlayer connection is formed by laser processing, and then subjected to desmear treatment and roughening treatment by an alkaline permanganate treatment or the like. (3) Subsequently, the substrate is subjected to electroless copper plating treatment, and then a pattern is formed using a resist, followed by copper electroplating, forming a circuit layer of copper. (4) Then, the resist is removed, and then flash etching for the electroless plating layer is conducted, forming a circuit of copper.

As mentioned above, as a method for forming a via in the interlayer insulating layer formed by curing a thermosetting resin film, laser processing is mainly used, but, the reduction of the via in diameter by irradiation with a laser using a laser processing machine, has a limitation. Further, in the formation of vias using a laser processing machine, via holes must be individually formed one by one, and, when forming a large number of vias in order to increase the density, such laser processing has a problem in that a lot of time is required for forming vias, causing the production efficiency to be poor.

Under the circumstances, as a method that enables formation of a large number of vias at the same time, a method has been proposed in which a plurality of small diameter vias are formed at the same time by a photolithography method using a photosensitive resin composition which contains an acid-modified vinyl group-containing epoxy resin, a photopolymerizable compound, a photopolymerization initiator, an inorganic filler, and a silane compound, wherein the amount of the inorganic filler contained is 10 to 80% by mass (see, for example, PTL 2).

PTL 2 has a description that a task is to suppress a lowering of the adhesion of the interlayer insulating layer or surface protective layer to copper plating due to the use of the photosensitive resin composition, instead of a conventional thermosetting resin composition, as a material for the interlayer insulating layer or surface protective layer, and another task is to achieve resolution of vias and adhesion to a substrate formed from a silicon material and chip parts, and these tasks have been achieved.

### CITATION LIST

### Patent Literature

PTL 1: JP 7-304931 A
PTL 2: JP 2017-116652 A

### SUMMARY OF INVENTION

### Technical Problem

Incidentally, a semiconductor package contains organic components constituting the insulating layer and inorganic components, such as a conductor layer and a semiconductor chip, and therefore a difference in the coefficient of thermal expansion between the organic components and the inorganic components is likely to cause a stress when the temperature changes, so that warpage, formation of cracks, or the like occurs. As a method for preventing the problem, there is a method in which an inorganic filler is added to the resin composition for forming the insulating layer so that the coefficient of thermal expansion of the resin composition becomes close to that of the inorganic components.

However, from the studies made by the present inventors, it has been found that when an inorganic filler is contained in the photosensitive resin film, a via formed by subjecting the photosensitive resin film to exposure and development has a shape such that, as compared to the diameter of the top portion of the via (hereinafter, frequently referred to as “top diameter”), which corresponds to the exposed surface, the diameter of the bottom portion of the via (hereinafter, frequently referred to as “bottom diameter”) is extremely small, i.e., a shape such that the via is considerably tapered as viewed in the cross-section of the via, so that excellent resolution cannot be obtained.

Accordingly, an object of the present disclosure is to provide a photosensitive resin film having excellent resolution and a printed wiring board and a semiconductor package each using the photosensitive resin film.

### Solution to Problem

The present inventors have conducted extensive and intensive studies. As a result, it has been found that the above-mentioned object can be achieved by the present disclosure. Specifically, the present disclosure includes the following embodiments [1] to [11].

[1] A photosensitive resin film containing (A) a photopolymerizable compound having an ethylenically unsaturated group and an acidic substituent and (B) an inorganic filler,
in which the amount of the inorganic filler (B) contained is 25% by volume or more, and
in which the cured product of the photosensitive resin film has a refractive index of 1.550 or more.

[2] The photosensitive resin film according to item [1] above, in which the inorganic filler (B) has a refractive index of 1.520 to 1.680.

[3] The photosensitive resin film according to item [1] or [2] above, in which the inorganic filler (B) is composite particles of silica and a metal oxide other than silica.

[4] The photosensitive resin film according to item [3] above, in which the composite particles of silica and a metal oxide other than silica are silica-titania composite particles.

[5] The photosensitive resin film according to any of items [1] to [4] above, in which the inorganic filler (B) is spherical.

[6] The photosensitive resin film according to any of items [1] to [5] above, further containing (C) a thermosetting resin.

[7] The photosensitive resin film according to any of items [1] to [6] above, further containing (D) a crosslinking agent.

[8] The photosensitive resin film according to any of items [1] to [7] above, further containing (E) a photopolymerization initiator.

[9] The photosensitive resin film according to any of items [1] to [8] above, which is for use in photo via formation.

[10] A printed wiring board including a cured product of the photosensitive resin film according to any of items [1] to [9] above.

[11] A semiconductor package including the printed wiring board according to item [10] above and a semiconductor element.

### Advantageous Effects of Invention

By the present disclosure, there can be provided a photosensitive resin film having excellent resolution and a printed wiring board and a semiconductor package each using the photosensitive resin film.

### BRIEF DESCRIPTION OF DRAWINGS

FIG. 1 is a diagrammatic view showing the laminating step (1).

FIG. 2 is a diagrammatic view showing the photo via forming step (2).

FIG. 3 is a diagrammatic view showing the roughening treatment step (3).

FIG. 4 is a diagrammatic view showing the circuit pattern forming step (4).

FIG. 5 is a diagrammatic view of a multilayered printed wiring board.

FIG. 6 is a diagrammatic view for explaining the taper angle.

### DESCRIPTION OF EMBODIMENTS

In a numerical value range described in the present disclosure, the upper limit value and the lower limit value of the numerical value range can be substituted by each value described in Examples below. In addition, the lower limit value and the upper limit value in the numerical value range are each arbitrarily combined with the lower limit value or the upper limit value of another numerical value range. In the expression “numerical value range AA to BB”, the numerical values AA and BB that are both ends are contained in the numerical value range as the lower limit value and the upper limit value, respectively.

In the present disclosure, for example, the expression “10 or more” means 10 and a numerical value exceeding 10, and, in the case of different numerical values, this is also adopted. For example, the expression “10 or less” means 10 and a numerical value less than 10, and, in the case of different numerical values, this is also adopted.

In the present disclosure, when a plurality of types of substances corresponding to each of the components of the photosensitive resin film are present, the content of each of the components in the photosensitive resin composition means the total content of the substances present in the photosensitive resin film unless otherwise specified.

In the present disclosure, the term “ring-forming carbon atom number” is the number of carbon atoms required for forming the ring, but the number of carbon atoms of a substituent of the ring is not included. For example, in both a cyclohexane skeleton and a methylcyclohexane skeleton, the ring-forming carbon atom number is 6. Further, the term “ring-forming atom number” is the number of atoms required for forming the ring, but the number of atoms of a substituent of the ring is not included. For example, in both a pyridine skeleton and a methylpyridine skeleton, the ring-forming atom number is 6.

The expression “XX (meth)acrylate” means one of or both of XX acrylate and XX methacrylate. Further, the term “(meth)acryloyl group” means one of or both of an acryloyl group and a methacryloyl group.

In the present disclosure, the term “resin components” means the below-mentioned component (A) and the like, and includes other components optionally contained (for example, components (C), (D), (E), (F), and (G) and the like), but does not include an inorganic compound, such as an inorganic filler (B) or a pigment (H). Further, the term “solids” means the nonvolatile matter contained in the photosensitive resin film, exclusive of water and the below-mentioned diluent, and includes a substance in a liquid state at room temperature. In the present description, the room temperature means 25° C.

Further, an embodiment having an arbitrary combination of the matters described in the present disclosure is included in the present embodiment.

### [Photosensitive Resin Film]

The photosensitive resin film of the present embodiment is a photosensitive resin film containing (A) a photopolymerizable compound having an ethylenically unsaturated group and an acidic substituent and (B) an inorganic filler,
in which the amount of the inorganic filler (B) contained is 25% by volume or more, and
in which the cured product of the photosensitive resin film has a refractive index of 1.550 or more.

The photosensitive resin film of the present embodiment is suitable for via formation by a photolithography method (frequently referred to as “photo via formation”), and therefore is advantageously used in formation of at least one member selected from the group consisting of a photo via and an interlayer insulating layer. In the present disclosure, with respect to the term “layer” as recited in, for example, the interlayer insulating layer, the “layer” includes a form of a solid layer, a form of a layer which is not a solid layer but at least a part of which is in an island-like shape, a form of a layer which is perforated, a form of a layer in which the interface between the layer and the adjacent layer is unclear, and the like. The expression “solid layer” means a layer in a sheet form which has not particularly been subjected to processing.

The photosensitive resin film of the present embodiment is advantageously used as a negative photosensitive resin film.

### <Refractive Index of the Cured Product of the Photosensitive Resin Film>

The cured product of the photosensitive resin film of the present embodiment has a refractive index of 1.550 or more.

The refractive index of the cured product is 1.550 or more, and therefore the photosensitive resin film of the present embodiment exhibits excellent resolution. The reason for this is not clear, but is presumed that when the refractive index of the cured product is 1.550 or more, diffusion of the energy ray entering the photosensitive resin film during the exposure is suppressed, so that curing of the shielded portion is suppressed.

From the same point of view, the refractive index of the cured product of the photosensitive resin film of the present embodiment is preferably 1.551 to 1.680, more preferably 1.552 to 1.640, further preferably 1.553 to 1.600.

The refractive index of the cured product of the photosensitive resin film can be measured by the method described in the Examples.

### <(A) Photopolymerizable Compound Having an Ethylenically Unsaturated Group and an Acidic Substituent>

The component (A) is a photopolymerizable compound having an ethylenically unsaturated group and an acidic substituent.

With respect to the component (A), the compounds can be used individually or in combination.

The component (A) has an ethylenically unsaturated group, and therefore is a compound that exhibits photopolymerizability, particularly radical polymerizability.

Examples of the ethylenically unsaturated groups of the component (A) include functional groups having photopolymerizability, such as a vinyl group, an allyl group, a propargyl group, a butenyl group, an ethynyl group, a phenylethynyl group, a maleimide group, a nadiimide group, and a (meth)acryloyl group. Of these, from the viewpoint of the reactivity and resolution of vias, a (meth)acryloyl group is preferred.

The component (A) has an acidic substituent from the viewpoint of enabling alkaline development.

Examples of the acidic substituents of the component (A) include a carboxy group, a sulfonic acid group, and a phenolic hydroxy group. Of these, from the viewpoint of the resolution of vias, a carboxy group is preferred.

The component (A) preferably has an acid value of 20 to 200 mg KOH/g, more preferably 40 to 180 mg KOH/g, further preferably 50 to 150 mg KOH/g. When the acid value of the component (A) is the lower limit or more, it is likely that the photosensitive resin film has excellent solubility in a dilute alkali solution, and, when the acid value of the component (A) is the upper limit or less, it is likely that excellent dielectric properties can be obtained. The acid value of the component (A) can be measured by the method described in the Examples.

Two types or more of the component (A) having different acid values can be used in combination, and, in such a case, it is preferred that a weighted average of the acid values of the two types or more of the component (A) is in any of the above-mentioned ranges.

The component (A) preferably has a weight average molecular weight (Mw) of 600 to 30,000, more preferably 800 to 25,000, further preferably 1,000 to 18,000. When the weight average molecular weight (Mw) of the component (A) is in the above range, it is likely that excellent bond strength to copper plating, excellent heat resistance, and excellent insulation reliability can be obtained. In the present disclosure, the weight average molecular weight is a value as determined by a gel permeation chromatography (GPC) method using tetrahydrofuran as a solvent and expressed in terms of the standard polystyrene, specifically, a value as measured in accordance with the method described in Examples.

From the viewpoint of the resolution of vias and bond strength to copper plating, the component (A) is preferably an acid-modified vinyl group-containing epoxy resin which is obtained by reacting (a3) a saturated group- or unsaturated group-containing polybasic acid anhydride with a compound [hereinafter, frequently referred to as “component (A′)”] obtained by modifying (a1) an epoxy resin with (a2) an ethylenically unsaturated group-containing organic acid. With respect to the acid-modified vinyl group-containing epoxy resin, the expression “acid-modified” means that the vinyl group has an acidic substituent, the term “vinyl group” means an ethylenically unsaturated group, and the term “epoxy resin” means that the epoxy resin is used as a raw material, and the acid-modified vinyl group-containing epoxy resin does not necessarily have an epoxy group, and need not have an epoxy group.

Hereinbelow, a preferred mode of the component (A) obtained from the epoxy resin (a1), ethylenically unsaturated group-containing organic acid (a2), and saturated group- or unsaturated group-containing polybasic acid anhydride (a3) is described.

((a1) Epoxy Resin)

The epoxy resin (a1) is preferably an epoxy resin having two or more epoxy groups.

With respect to the epoxy resin (a1), the epoxy resins can be used individually or in combination.

The epoxy resin (a1) is classified into an epoxy resin of a glycidyl ether type, an epoxy resin of a glycidyl amine type, an epoxy resin of a glycidyl ester type, and the like. Of these, an epoxy resin of a glycidyl ether type is preferred.

The epoxy resin (a1) can be classified into various types of epoxy resins according to the main skeleton, and can be classified into an epoxy resin having an alicyclic skeleton, a novolak epoxy resin, a bisphenol epoxy resin, an aralkyl epoxy resin, other epoxy resins, and the like. Of these, an epoxy resin having an alicyclic skeleton, a novolak epoxy resin, and a bisphenol epoxy resin are preferred, and a novolak epoxy resin and a bisphenol epoxy resin are more preferred.

Examples of novolak epoxy resins include bisphenol novolak epoxy resins, such as a bisphenol A novolak epoxy resin, a bisphenol F novolak epoxy resin, and a bisphenol S novolak epoxy resin; a phenolic novolak epoxy resin, a cresol novolak epoxy resin, a biphenyl novolak epoxy resin, and a naphthol novolak epoxy resin. Of these, a cresol novolak epoxy resin is preferred.

Examples of bisphenol epoxy resins include a bisphenol A epoxy resin, a bisphenol F epoxy resin, and a bisphenol S epoxy resin. Of these, a bisphenol A epoxy resin is preferred.

((a2) Ethylenically Unsaturated Group-Containing Organic Acid)

The ethylenically unsaturated group-containing organic acid (a2) is preferably an ethylenically unsaturated group-containing monocarboxylic acid.

As examples of the ethylenically unsaturated groups of the component (a2), there can be mentioned the same as those mentioned above as examples of the ethylenically unsaturated groups of the component (A).

Examples of the component (a2) include acrylic acid derivatives, such as acrylic acid, a dimer of acrylic acid, methacrylic acid, β-furfurylacrylic acid, β-styrylacrylic acid, cinnamic acid, crotonic acid, and α-cyanocinnamic acid; a half ester compound which is a reaction product of a hydroxy group-containing acrylate and a dibasic acid anhydride; and a half ester compound which is a reaction product of a vinyl group-containing monoglycidyl ether or vinyl group-containing monoglycidyl ester and a dibasic acid anhydride.

With respect to the component (a2), the compounds can be used individually or in combination.

In the reaction of the component (a1) and the component (a2), the amount of the component (a2) used, relative to one equivalent of the epoxy group of the component (a1), is preferably 0.6 to 1.05 equivalent, more preferably 0.7 to 1.02 equivalent, further preferably 0.8 to 1.0 equivalent. When the component (a1) and the component (a2) in the above-mentioned ratio are subjected to reaction, it is likely that the component (A) is improved in photopolymerizability, so that the obtained photosensitive resin film has improved resolution of vias.

It is preferred that the component (a1) and the component (a2) are reacted in a state such that the components (a1) and (a2) are dissolved in an organic solvent.

In the reaction of the component (a1) and the component (a2), if necessary, a catalyst for promoting the reaction, a polymerization inhibitor for preventing polymerization during the reaction, or the like can be used.

With respect to the component (A′) obtained by reacting the component (a1) and the component (a2) as mentioned above, when an ethylenically unsaturated group-containing monocarboxylic acid is used as the component (a2), the component (A′) has a hydroxy group formed due to a ring-opening addition reaction of the epoxy group of the component (a1) and the carboxy group of the component (a2). Then, by further reacting the component (a3) with the component (A′), there can be obtained an acid-modified vinyl group-containing epoxy resin which is formed by half-esterification of the hydroxy group of the component (A′) (including the hydroxy group originally present in the component (a1)) and the acid anhydride group of the component (a3).

((a3) Saturated Group- or Unsaturated Group-Containing Polybasic Acid Anhydride)

The component (a3) can be one which contains a saturated group, or can be one which contains an unsaturated group. Examples of the component (a3) include succinic anhydride, maleic anhydride, tetrahydrophthalic anhydride, phthalic anhydride, methyltetrahydrophthalic anhydride, ethyltetrahydrophthalic anhydride, hexahydrophthalic anhydride, methylhexahydrophthalic anhydride, ethylhexahydrophthalic anhydride, and itaconic anhydride. Of these, from the viewpoint of the resolution of vias, tetrahydrophthalic anhydride is preferred. With respect to the component (a3), the polybasic acid anhydrides can be used individually or in combination.

In the reaction of the component (A′) and the component (a3), for example, when 0.1 to 1.0 equivalent of the component (a3) is reacted, relative to one equivalent of the hydroxy group in the component (A′), the acid value of the acid-modified vinyl group-containing epoxy resin can be appropriately controlled.

With respect to the amount of the component (A) contained in the photosensitive resin film of the present embodiment, there is no particular limitation, but, from the viewpoint of the resolution, heat resistance, and chemical resistance, the amount of the component (A) is preferably 10 to 80% by mass, more preferably 30 to 70% by mass, further preferably 50 to 65% by mass, based on the total mass of the resin components of the photosensitive resin film.

### <(B) Inorganic Filler>

The photosensitive resin film of the present embodiment further contains an inorganic filler as a component (B).

The photosensitive resin film of the present embodiment contains the inorganic filler (B), and therefore is improved in the low coefficient of thermal expansion, heat resistance, and flame retardancy.

With respect to the inorganic filler (B), the inorganic fillers can be used individually or in combination.

With respect to the inorganic filler (B), there is no particular limitation, but examples of inorganic fillers include silica, alumina, titanium oxide, mica, beryllia, barium titanate, potassium titanate, strontium titanate, calcium titanate, aluminum carbonate, magnesium hydroxide, aluminum hydroxide, aluminum silicate, calcium carbonate, calcium silicate, magnesium silicate, silicon nitride, boron nitride, clay, a molybdic acid compound, talc, aluminum borate, silicon carbide, and composite particles of two or more metal oxides.

Of these, from the viewpoint of easily controlling the refractive index of the cured product of the photosensitive resin film to be in the range of 1.550 or more, composite particles of two or more metal oxides are preferred, and composite particles of silica and a metal oxide other than silica are more preferred.

In the composite particles of silica and a metal oxide other than silica, examples of the metal oxides other than silica include titania (titanium oxide), zirconia (zirconium oxide), alumina (aluminum oxide), boron oxide, calcium oxide, and zinc oxide. Of these, the metal oxide other than silica is preferably titania from the viewpoint of easily controlling the refractive index of the cured product of the photosensitive resin film to be in the range of 1.550 or more. That is, the composite particles of silica and a metal oxide other than silica are preferably silica-titania composite particles.

With respect to the volume average particle diameter of the component (B), there is no particular limitation, but the volume average particle diameter of the component (B) is preferably 0.01 to 20 μm, more preferably 0.1 to 10 μm, further preferably 0.2 to 1 μm, especially preferably 250 to 700 nm.

In the present description, the volume average particle diameter is a value determined as a particle diameter corresponding to 50% cumulative value (in terms of a volume) in the particle size distribution measured with respect to the particles dispersed in a solvent at a refractive index of 1.38 using a submicron particle analyzer (trade name: N5, manufactured by Beckman Coulter, Inc.) in accordance with International Standard ISO 13321.

With respect to the refractive index of the component (B), there is no particular limitation, but the refractive index of the component (B) is preferably 1.520 to 1.680, more preferably 1.530 to 1.640, further preferably 1.535 to 1.600.

As examples of shapes of the inorganic filler (B), there can be mentioned a spherical shape and a crushed form, and, of these, from the viewpoint of easily controlling the refractive index of the cured product of the photosensitive resin film of the present embodiment to be in the range of 1.550 or more, the inorganic filler (B) is preferably spherical.

In the present embodiment, the term “spherical” means that the particles have a circularity of 90 or more, as determined from the following formula using an area and a circumferential length measured from a photomicrograph of the particles to be observed.

Circularity={4π×(Area)÷(Circumferential length)²}×100

Observation of the particles can be made, for example, using a scanning electron microscope (SEM) at a magnification of 5,000 times, and an average of areas and an average of circumferential lengths measured with respect to 10 arbitrary particles can be respectively used as the area and circumferential length for the above formula.

### (Amount of the Component (B) Contained)

From the viewpoint of the resolution and low thermal expansion, the amount of the component (B) contained in the photosensitive resin film of the present embodiment is 25% by volume or more, preferably 30 to 80% by volume, more preferably 40 to 70% by volume, further preferably 50 to 60% by volume.

From the viewpoint of further improving the resolution, the amount of the component (B) contained in the photosensitive resin film of the present embodiment can be 26 to 55% by volume, can be 27 to 45% by volume, or can be 28 to 35% by volume.

From the viewpoint of the resolution and low thermal expansion, the amount of the component (B) contained in the photosensitive resin film of the present embodiment, in terms of a mass, is preferably 40 to 90% by mass, more preferably 50 to 85% by mass, further preferably 60 to 80% by mass.

From the viewpoint of further improving the resolution, the amount of the component (B) contained in the photosensitive resin film of the present embodiment, in terms of a mass, can be 42 to 75% by mass, can be 43 to 65% by mass, or can be 45 to 55% by mass.

### <(C) Thermosetting Resin>

The photosensitive resin film of the present embodiment preferably further contains a thermosetting resin as a component (C). The component (C) does not include the component (A).

When the photosensitive resin film of the present embodiment contains the thermosetting resin (C), it is likely that the bond strength to copper plating and the insulation reliability as well as the heat resistance are improved.

With respect to the component (C), the thermosetting resins can be used individually or in combination.

Examples of thermosetting resins include an epoxy resin, a phenolic resin, an unsaturated imide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin. The thermosetting resin is not particularly limited to these resins, and a known thermosetting resin can be used. Of these, from the viewpoint of the bond strength to copper plating, insulation reliability, and heat resistance, an epoxy resin is preferred.

The epoxy resin is preferably an epoxy resin having two or more epoxy groups. The epoxy resin is classified into an epoxy resin of a glycidyl ether type, an epoxy resin of a glycidyl amine type, an epoxy resin of a glycidyl ester type, and the like. Of these, an epoxy resin of a glycidyl ether type is preferred.

Further, the epoxy resin is classified into various types of epoxy resins according to the main skeleton, and the epoxy resins of the above types are individually further classified as follows. Specifically, the epoxy resins are classified into bisphenol epoxy resins, such as a bisphenol A epoxy resin, a bisphenol F epoxy resin, and a bisphenol S epoxy resin; bisphenol novolak epoxy resins, such as a bisphenol A novolak epoxy resin and a bisphenol F novolak epoxy resin; novolak epoxy resins other than the bisphenol novolak epoxy resins, such as a phenolic novolak epoxy resin, a cresol novolak epoxy resin, and a biphenyl novolak epoxy resin; a phenolic aralkyl epoxy resin; a stilbene epoxy resin; naphthalene skeleton-containing epoxy resins, such as a naphthol novolak epoxy resin, a naphthol epoxy resin, a naphthol aralkyl epoxy resin, and a naphthylene ether epoxy resin; a biphenyl epoxy resin; a biphenylaralkyl epoxy resin; a xylylene epoxy resin; a dihydroanthracene epoxy resin; alicyclic epoxy resins, such as a saturated dicyclopentadiene epoxy resin; a heterocyclic epoxy resin; a spiro ring-containing epoxy resin; a cyclohexanedimethanol epoxy resin; a trimethylol epoxy resin; an aliphatic chain epoxy resin; a rubber-modified epoxy resin; and the like. Of these, from the viewpoint of the heat resistance, electrical insulation reliability, development properties, and bond strength to copper plating, a biphenylaralkyl epoxy resin and a biphenyl epoxy resin are preferred.

With respect to the equivalent ratio of the epoxy group of the component (C) to the acidic substituent of the component (A) [epoxy group/acidic substituent] in the photosensitive resin film of the present embodiment, there is no particular limitation, but, from the viewpoint of the insulation reliability, dielectric properties, heat resistance, and bond strength to copper plating, the equivalent ratio is preferably 0.5 to 6.0, more preferably 0.7 to 4.0, further preferably 0.8 to 2.0, especially preferably 0.9 to 1.8.

When the photosensitive resin film of the present embodiment contains the component (C), with respect to the amount of the component (C) contained, there is no particular limitation, but, from the viewpoint of the insulation reliability, dielectric properties, heat resistance, and bond strength to copper plating, the amount of the component (C) is preferably 1 to 50% by mass, more preferably 5 to 40% by mass, further preferably 15 to 40% by mass, based on the total mass of the resin components of the photosensitive resin film.

### <(D) Crosslinking Agent>

The photosensitive resin film of the present embodiment preferably further contains a crosslinking agent as a component (D). The crosslinking agent is preferably a crosslinking agent having two or more ethylenically unsaturated groups and having no acidic substituent. The crosslinking agent is reacted with the ethylenically unsaturated group of the component (A) to increase the crosslinking density of the photosensitive resin film after being cured. Accordingly, when the photosensitive resin film of the present embodiment contains a crosslinking agent, it is likely that the heat resistance and dielectric properties are improved.

With respect to the component (D), the crosslinking agents can be used individually or in combination.

Examples of the component (D) include a bifunctional monomer having two or more ethylenically unsaturated groups and a polyfunctional monomer having three or more ethylenically unsaturated groups. The component (D) preferably contains the polyfunctional monomer.

As examples of the ethylenically unsaturated groups of the component (D), there can be mentioned the same as those mentioned above as examples of the ethylenically unsaturated groups of the component (A), and a preferred mode of the ethylenically unsaturated group of the component (D) is the same as those for the component (A).

Examples of the bifunctional monomers include aliphatic di(meth)acrylates, such as trimethylolpropane di(meth)acrylate, polypropylene glycol di(meth)acrylate, and polyethylene glycol di(meth)acrylate; di(meth)acrylates having an alicyclic skeleton, such as dicyclopentadiene di(meth)acrylate and tricyclodecanedimethanol di(meth)acrylate; and aromatic di(meth)acrylates, such as 2,2-bis(4-(meth)acryloxypolyethoxypolypropoxyphenyl) propane and bisphenol A diglycidyl ether di(meth)acrylate.

Of these, from the viewpoint of obtaining more excellent dielectric properties, a di(meth)acrylate having an alicyclic skeleton is preferred, and tricyclodecanedimethanol diacrylate is more preferred.

Examples of the polyfunctional monomers include (meth)acrylate compounds having a trimethylolpropane-derived skeleton, such as trimethylolpropane tri(meth)acrylate; (meth)acrylate compounds having a tetramethylolmethane-derived skeleton, such as tetramethylolmethane tri(meth)acrylate and tetramethylolmethane tetra(meth)acrylate; (meth)acrylate compounds having a pentaerythritol-derived skeleton, such as pentaerythritol tri(meth)acrylate and pentaerythritol tetra(meth)acrylate; (meth)acrylate compounds having a dipentaerythritol-derived skeleton, such as dipentaerythritol penta(meth)acrylate and dipentaerythritol hexa(meth)acrylate; (meth)acrylate compounds having a ditrimethylolpropane-derived skeleton, such as ditrimethylolpropane tetra(meth)acrylate; and (meth)acrylate compounds having a diglycerol-derived skeleton. Of these, from the viewpoint of the resolution of vias and bond strength to copper plating, (meth)acrylate compounds having a dipentaerythritol-derived skeleton are preferred, and dipentaerythritol hexa(meth)acrylate is more preferred.

The expression “(meth)acrylate compound having a XXX-derived skeleton” (‘XXX’ is a name of compound) means an ester compound of XXX and (meth)acrylic acid, and the ester compound includes a compound modified with an alkyleneoxy group.

When the photosensitive resin film of the present embodiment contains the component (D), with respect to the amount of the component (D) contained, there is no particular limitation, but, from the viewpoint of the heat resistance and dielectric properties, the amount of the component (D) is preferably 5 to 50 parts by mass, more preferably 10 to 40 parts by mass, further preferably 15 to 30 parts by mass, relative to 100 parts by mass of the component (A).

### <(E) Photopolymerization Initiator>

The photosensitive resin film of the present embodiment preferably further contains a photopolymerization initiator as a component (E). When the photosensitive resin film of the present embodiment contains the photopolymerization initiator (E), it is likely that the resolution of vias is improved.

With respect to the photopolymerization initiator (E), the photopolymerization initiators can be used individually or in combination. From the viewpoint of the resolution of vias, the photosensitive resin film of the present embodiment preferably contains two types or more of the component (E).

With respect to the photopolymerization initiator (E), there is no particular limitation as long as the initiator is capable of causing an ethylenically unsaturated group to undergo photopolymerization, and the photopolymerization initiator (E) can be appropriately selected from photopolymerization initiators generally used.

Examples of the photopolymerization initiators (E) include benzoin compounds, such as benzoin, benzoin methyl ether, and benzoin isopropyl ether; acetophenone compounds, such as acetophenone, 2,2-dimethoxy-2-phenylacetophenone, 2,2-diethoxy-2-phenylacetophenone, 1,1-dichloroacetophenone, 1-hydroxycyclohexyl phenyl ketone, 2-benzyl-2-dimethylamino-1-(4-morpholinophenyl)-1-butanone, 2-[4-(methylthio)benzoyl]-2-(4-morpholinyl)propane, and N,N-dimethylaminoacetophenone; anthraquinone compounds, such as 2-methylanthraquinone, 2-ethylanthraquinone, 2-tert-butylanthraquinone, 1-chloroanthraquinone, 2-amylanthraquinone, and 2-aminoanthraquinone; ketal compounds, such as acetophenone dimethyl ketal and benzyl dimethyl ketal; acridine compounds, such as 9-phenylacridine and 1,7-bis(9,9′-acridinyl)heptane; acylphosphine oxide compounds, such as bis(2,4,6-trimethylbenzoyl)phenylphosphine oxide; and oxime ester compounds, such as 1,2-octanedione-1-[4-(phenylthio)phenyl]-2-(O-benzoyloxime), 1-[9-ethyl-6-(2-methylbenzoyl)-9H-carbazol-3-yl]ethanone 1-(O-acetyloxime), and 1-phenyl-1,2-propanedione-2-[O-(ethoxycarbonyl) oxime]. Of these, 2-methyl-4′-methylthio-2-morpholinopropiophene is preferred.

When the photosensitive resin film of the present embodiment contains the component (E), with respect to the amount of the component (E) contained, there is no particular limitation, but, from the viewpoint of the resolution and heat resistance, the amount of the component (E) is preferably 0.01 to 20% by mass, more preferably 0.05 to 10% by mass, further preferably 0.05 to 3% by mass, based on the total mass of the resin components of the photosensitive resin film.

### <(F) Photosensitizer>

The photosensitive resin film of the present embodiment preferably optionally contains a photosensitizer as a component (F).

With respect to the photosensitizer (F), the photosensitizers can be used individually or in combination. From the viewpoint of the resolution of vias, the photosensitive resin film of the present embodiment can contain two types or more of the component (F).

Examples of the photosensitizers (F) include thioxanthone compounds, such as 2,4-dimethylthioxanthone, 2,4-diethylthioxanthone, 2-chlorothioxanthone, and 2,4-diisopropylthioxanthone; tertiary amines, such as a trialkylamine and triethanolamine; alkyl dialkylaminobenzoates, such as ethyl N,N-dimethylaminobenzoate and amyl N,N-dimethylaminobenzoate; bis(dialkylamino)benzophenones, such as 4,4′-bis(dimethylamino)benzophenone and 4,4′-bis(diethylamino)benzophenone; phosphine compounds, such as triphenylphosphine; toluidine compounds, such as N,N-dimethyltoluidine; anthracene compounds, such as 9,10-dimethoxyanthracene, 2-ethyl-9,10-dimethoxyanthracene, and 2-ethyl-9,10-diethoxyanthracene; perylene compounds; and coumarin compounds. Of these, from the viewpoint of the resolution of vias and improvement of the shape of vias, 2,4-diethylthioxanthone and 4,4′-bis(diethylamino)benzophenone are preferred.

When the photosensitive resin film of the present embodiment contains the component (F), with respect to the amount of the component (F) contained, there is no particular limitation, but, from the viewpoint of easily controlling the degree of cure of the photosensitive resin film to be in an appropriate range, the amount of the component (F) is preferably 0.01 to 5% by mass, more preferably 0.05 to 3% by mass, further preferably 0.1 to 1% by mass, based on the total mass of the resin components of the photosensitive resin film.

### <(G) Coupling Agent>

The photosensitive resin film of the present embodiment preferably optionally contains a coupling agent as a component (G).

With respect to the coupling agent (G), the coupling agents can be used individually or in combination.

Examples of the coupling agents (G) include an aminosilane coupling agent, an epoxy silane coupling agent, a phenylsilane coupling agent, an alkylsilane coupling agent, an alkenylsilane coupling agent, an alkynylsilane coupling agent, a haloalkylsilane coupling agent, a siloxane coupling agent, a hydrosilane coupling agent, a silazane coupling agent, an alkoxysilane coupling agent, a chlorosilane coupling agent, a (meth)acrylsilane coupling agent, an isocyanurate silane coupling agent, an ureidosilane coupling agent, a mercaptosilane coupling agent, a sulfide silane coupling agent, and an isocyanate silane coupling agent. Of these, a (meth)acrylsilane coupling agent is preferred, and 3-methacryloxypropyltrimethoxysilane is more preferred.

When the photosensitive resin film of the present embodiment contains the component (G), with respect to the amount of the component (G) contained, there is no particular limitation, but the amount of the component (G) is preferably 0.01 to 5% by mass, more preferably 0.05 to 3% by mass, further preferably 0.1 to 1% by mass, based on the total mass of the resin components of the photosensitive resin film.

### <(H) Pigment>

The photosensitive resin film of the present embodiment preferably optionally contains a pigment as a component (H).

With respect to the pigment (H), the pigments can be used individually or in combination.

Examples of the pigments (H) include phthalocyanine blue, phthalocyanine green, iodine green, diazo yellow, crystal violet, titanium oxide, carbon black, and naphthalene black.

When the photosensitive resin film of the present embodiment contains the component (H), with respect to the amount of the component (H) contained, there is no particular limitation, but the amount of the component (H) is preferably 0.01 to 5% by mass, more preferably 0.05 to 3% by mass, further preferably 0.1 to 1.5% by mass, based on the total mass of the resin components of the photosensitive resin film.

### <(I) Additional Component>

The photosensitive resin film of the present embodiment, if necessary, can contain an additional component, such as an elastomer, an organic filler, a curing agent, a curing accelerator, an adhesive auxiliary, a foam stabilizer, a polymerization inhibitor, a thickening agent, or a flame retardant.

The amount of the component (I) contained can be appropriately selected according to the purpose of each additional component, but, with respect to each of the additional components, the amount of the component (I) contained is preferably 0.01 to 20% by mass, and can be 0.05 to 10% by mass, or can be 0.1 to 1% by mass, based on the total mass of the resin components of the photosensitive resin film.

### <Thickness of the Photosensitive Resin Film>

With respect to the thickness of the photosensitive resin film of the present embodiment, there is no particular limitation, but, from the viewpoint of the insulation properties and reduction of the thickness of the printed wiring board, the thickness of the photosensitive resin film is preferably 1 to 100 μm, more preferably 3 to 50 μm, further preferably 5 to 40 μm.

### <Use of the Photosensitive Resin Film>

The photosensitive resin film of the present embodiment is suitable for via formation by a photolithography method (frequently referred to as “photo via formation”), and therefore the present disclosure provides a photosensitive resin film for use in photo via formation, which is formed from the photosensitive resin film of the present embodiment.

The photosensitive resin film of the present embodiment is useful as an interlayer insulating layer for printed wiring board, and further useful in the solder resist application.

### <Method for Producing the Photosensitive Resin Film>

The photosensitive resin film of the present embodiment can be produced by forming a film from a photosensitive resin composition containing the components constituting the photosensitive resin film of the present embodiment.

The photosensitive resin composition can be obtained by kneading and mixing the components by means of a roll mill, a bead mill, or the like. From the viewpoint of facilitating application of the composition, the photosensitive resin composition can be, if necessary, in the form of a varnish containing a diluent.

As a method for forming a film from the photosensitive resin composition, preferred is a method in which the photosensitive resin composition in the form of a varnish is applied to a carrier film and dried.

Examples of carrier films include polyesters, such as polyethylene terephthalate and polybutylene terephthalate; and polyolefins, such as polypropylene and polyethylene. The carrier film preferably has a thickness of 5 to 100 μm, more preferably 7 to 50 μm, further preferably 10 to 30 μm.

As examples of methods for applying the photosensitive resin composition in the form of a varnish to a carrier film, there can be mentioned a method in which the composition is applied by a known application apparatus, such as a comma coater, a bar coater, a kiss coater, a roll coater, a gravure coater, or a die coater.

In drying after the application of the composition, a dryer using hot-air drying, a far infrared ray, or a near infrared ray can be used. The drying temperature is preferably 60 to 150° C., more preferably 70 to 120° C., further preferably 80 to 110° C. The drying time is preferably 1 to 60 minutes, more preferably 2 to 30 minutes, further preferably 5 to 20 minutes.

With respect to the photosensitive resin film of the present embodiment, a protective film can be formed on the surface of the photosensitive resin film on the side opposite to the surface in contact with the carrier film. As a protective film, a polymer film, such as polyethylene or polypropylene, can be used.

### [Printed Wiring Board]

The printed wiring board of the present embodiment includes a cured product of the photosensitive resin film of the present embodiment. In other words, the printed wiring board contains an interlayer insulating layer formed using the photosensitive resin film of the present embodiment. The expression that the printed wiring board “contains an interlayer insulating layer” indicates both that the printed wiring board contains an interlayer insulating layer as such, and that the printed wiring board contains the interlayer insulating layer which has been subjected, for example, to processing, such as via formation, a treatment, such as a roughening treatment, and wiring formation.

### [Method for Producing a Printed Wiring Board]

The method for producing a printed wiring board according to an embodiment of the present disclosure (hereinafter, frequently referred to simply as “the present embodiment”) is a method for producing a printed wiring board, including the following steps (1) to (4):
(1): laminating the photosensitive resin film of the present embodiment on one surface or both surfaces of a circuit substrate (hereinafter, referred to as “laminating step (1)”);
(2): subjecting the photosensitive resin film laminated in the step (1) to exposure and development to form an interlayer insulating layer having a via (hereinafter, referred to as “photo via forming step (2)”);
(3): subjecting the surface of the via and the interlayer insulating layer to roughening treatment (hereinafter, referred to as “roughening treatment step (3)”); and
(4): forming a circuit pattern on the interlayer insulating layer (hereinafter, referred to as “circuit pattern forming step (4)”).

In the present disclosure, as described above, a predetermined procedure is frequently referred to as “XX step”, but the “XX step” is not limited to the mode specifically described in the present disclosure.

The steps are individually described below.

### (Laminating Step (1))

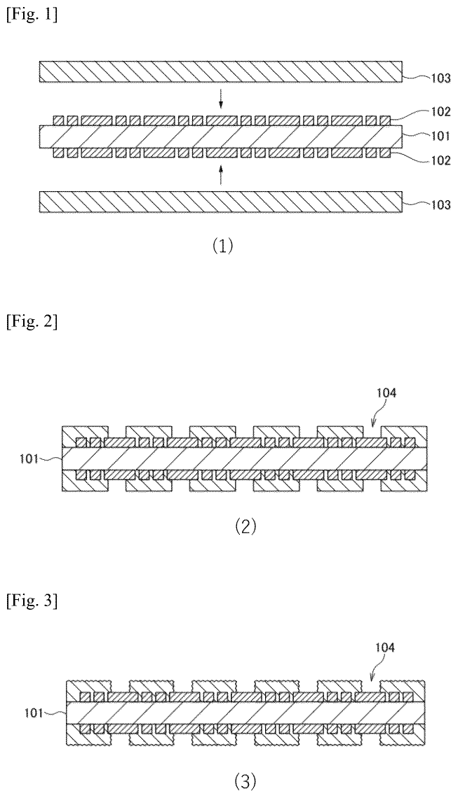

The laminating step (1) is a step of laminating the photosensitive resin film of the present embodiment on one surface or both surfaces of a circuit substrate (a substrate 101 having a circuit pattern 102) using a vacuum laminator (see FIG. 1).

When a protective film is formed on the photosensitive resin film, the protective film is peeled off or removed, and then the photosensitive resin film can be laminated on the circuit substrate while pressurizing and heating in a state such that the photosensitive resin film is in contact with the circuit substrate.

The lamination can be conducted, if necessary, for example, after pre-heating the photosensitive resin film and circuit substrate, at a pressure-bonding temperature of 70 to 130° C. and at a pressure-bonding pressure of 0.1 to 1.0 MPa under a reduced pressure, i.e., an air pressure of 20 mmHg (26.7 hPa) or less, but the conditions are not particularly limited to those mentioned above. Further, the method for lamination can be any of a batchwise system and a continuous system using a roll.

Finally, the photosensitive resin film laminated on the circuit substrate is cooled to about 25° C., forming an interlayer insulating layer 103. When the photosensitive resin film has a carrier film, the carrier film can be peeled off in this instance, or can be peeled off after exposure as described below.

### (Photo Via Forming Step (2))

In the photo via forming step (2), at least part of the photosensitive resin film laminated on the circuit substrate is subjected to exposure, and then subjected to development. In the exposure, a portion of the film irradiated with an active light is photo-cured to form a pattern. With respect to the exposure method, there is no particular limitation, and, for example, a method (mask exposure method) can be employed in which the photosensitive resin film is irradiated with an active light for an intended image through a negative or positive mask pattern called an artwork, or a method can be employed in which the photosensitive resin film is irradiated with an active light for an intended image by a direct imaging exposure method, such as a laser direct imaging (LDI) exposure method or a digital light processing (DLP) exposure method.

As a light source for an active light, a known light source can be used. Specific examples of light sources include a carbon-arc lamp, a mercury vapor-arc lamp, a high-pressure mercury lamp, a xenon lamp, a gas laser, such as an argon laser; solid-state lasers, such as a YAG laser; and those which effectively emit a ray of ultraviolet light or visible light, such as a semiconductor laser. The exposure dose is appropriately selected according to the light source used, the thickness of the photosensitive resin film, and the like, but, for example, when the photosensitive resin film having a thickness of 1 to 100 μm is irradiated with an ultraviolet light from a high-pressure mercury lamp, generally, the exposure dose is preferably about 10 to 1,000 mJ/cm², more preferably 50 to 700 mJ/cm², further preferably 150 to 550 mJ/cm², especially preferably 250 to 500 mJ/cm².

In the development, the uncured portion of the photosensitive resin film is removed from the substrate, so that the photo-cured portion is formed as an interlayer insulating layer on the substrate.

When a carrier film is present on the photosensitive layer, the carrier film is removed and then removal of the unexposed portion (development) is conducted. With respect to the development method, there are wet development and dry development, and any of wet development and dry development can be employed, but wet development is widely used, and wet development can be employed in the present embodiment.

In the wet development, development is performed by a known development method using a developer corresponding to the photosensitive resin film. Examples of development methods include methods using a dipping process, a puddle process, a spraying process, brushing, slapping, scrapping, swing immersion, or the like. Of these, from the viewpoint of improving the resolution of vias, a spraying process is preferred, and, among the spraying process, a high-pressure spraying process is more preferred. The development can be conducted by a single method, but can be performed by a combination of two or more methods.

The constituents of the developer are appropriately selected according to the constituents of the photosensitive resin film. Examples of developers include an aqueous alkaline solution, an aqueous developer, and an organic solvent developer, and, of these, an aqueous alkaline solution is preferred.

In the photo via forming step (2), exposure and development are conducted, and then the interlayer insulating layer can be further cured by, if necessary, performing post-UV-curing at an exposure dose of about 0.2 to 10 J/cm² (preferably 0.5 to 5 J/cm²) and post-heat-curing at a temperature of about 60 to 250° C. (preferably 120 to 200° C.), and the interlayer insulating layer is preferably further cured.

By the above-described method, an interlayer insulating layer having a via 104 is formed (see FIG. 2).

With respect to the size of the via 104 formed by the present step, there is no particular limitation, and, for example, the size can be 5 to 300 μm, can be 10 to 100 μm, or can be 15 to 80 μm. The photosensitive resin film of the present embodiment has excellent resolution, and therefore is advantageously used for forming small diameter vias, and, from the above viewpoint, the size of the via can be less than 40 μm, or can be 35 μm or less. The size of the via means the maximum length of the via when the interlayer insulating layer is viewed as a plane, and, when the via is circular, the size of the via means a diameter.

### (Roughening Treatment Step (3))

In the roughening treatment step (3), the surface of the via and interlayer insulating layer is subjected to roughening treatment (see FIG. 3). By the roughening treatment, a very small uneven anchor is formed in the surface of the via and interlayer insulating layer.

With respect to the roughening treatment method, there is no particular limitation, and a known roughening treatment method for via and interlayer insulating layer can be employed. The roughening treatment method is not particularly limited, but examples include a method in which a roughening treatment is conducted using a roughening liquid, and a method in which a roughening treatment is conducted by dry etching.

### (Circuit Pattern Forming Step (4))

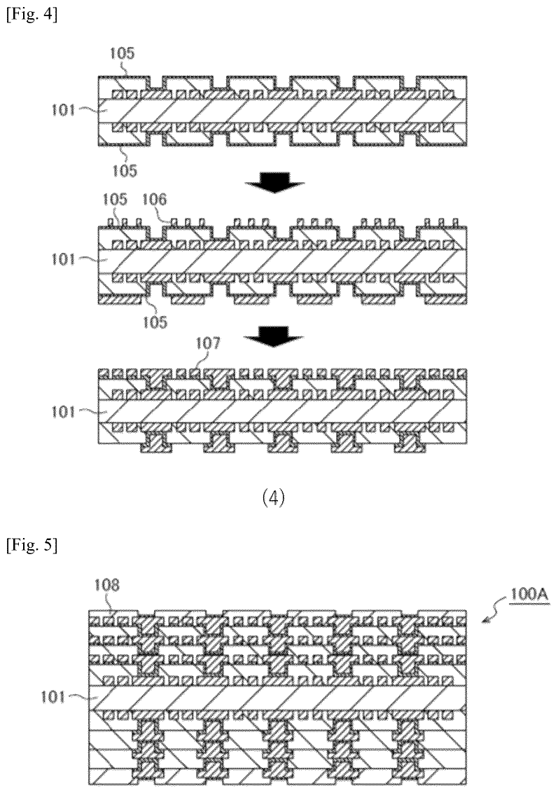

The circuit pattern forming step (4) is a step of forming a circuit pattern on the interlayer insulating layer after the roughening treatment step (3) (see FIG. 4).

From the viewpoint of the formation of a scaled-down wiring, formation of a circuit pattern is preferably conducted by a semi-additive process. The formation of a circuit pattern as well as conduction of vias are performed by a semi-additive process.

After forming the circuit pattern, a post-baking treatment is preferably conducted. The post-baking treatment enables the unreacted heat-curable component to be satisfactorily heat-cured, and thus is likely to further improve the insulation reliability, curing properties, and bond strength to copper plating. The heat-curing conditions vary depending on the type of the resin composition and the like, but are preferably conditions such that the curing temperature is 150 to 240° C. and the curing time is 15 to 100 minutes. The post-baking treatment completes a series of production process for a printed wiring board 100A in accordance with a photo via method, and the present process is repeated according to the required number of interlayer insulating layers, producing a multilayered printed wiring board 100A (see FIG. 5). Then, a solder resist layer 108 is preferably formed as the outermost layer.

### [Semiconductor Package]

In the present disclosure, there is also provided a semiconductor package including the printed wiring board of the present embodiment and a semiconductor element. The semiconductor package of the present embodiment can be produced by mounting a semiconductor element, such as a semiconductor chip or a memory, on the printed wiring board of the present embodiment at a predetermined position, and then subjecting the semiconductor element to encapsulation using a resin for encapsulation or the like.

### EXAMPLES

Hereinbelow, the present embodiment will be described in more detail with reference to the following Examples, which should not be construed as limiting the scope of the present disclosure. An acid value and a weight average molecular weight of the component (A) were measured in accordance with the methods described below. Further, using the photosensitive resin film obtained in each of the Examples, properties were evaluated by the methods described below.

### <Measurement Method for Acid Value>

An acid value of the component (A) was determined from the amount of the aqueous potassium hydroxide solution required for neutralizing the component (A).

### <Measurement Method for Weight Average Molecular Weight>

A weight average molecular weight of the component (A) was a value as measured using the GPC measuring apparatus and conditions for measurement shown below, and determined using a conversion calibration curve obtained from the standard polystyrene. In the preparation of a calibration curve, as the standard polystyrene, 5 sample sets (“PStQuick MP-H” and “PStQuick B”, manufactured by Tosoh Corporation) were used.

### (GPC Measuring Apparatus)

Apparatus: High speed GPC apparatus “HCL-8320GPC”, detector: differential refractometer or UV, manufactured by Tosoh Corporation.
Column: Column TSKgel SuperMultipore HZ-H (column length: 15 cm; column inner diameter: 4.6 mm), manufactured by Tosoh Corp.

### (Conditions for Measurement)

Solvent: Tetrahydrofuran (THF)
Temperature for measurement: 40° C.
Flow rate: 0.35 ml/minute
Sample concentration: 10 mg/THF 5 ml
Sample amount per injection: 20 μl

### <Measurement Method for Refractive Index of the Cured Product of the Photosensitive Resin Film>

While removing the protective film from the “photosensitive resin film having a carrier film and a protective film” produced in each of Examples, the exposed photosensitive resin film was laminated on a silicon wafer using a press-system vacuum laminator (trade name “MVLP-500”, manufactured by Meiki Co., Ltd.) at a pressure-bonding pressure of 0.4 MPa, at a press heating plate temperature of 80° C., for an evacuation time of 25 seconds, for a lamination pressing time of 25 seconds, and under an air pressure of 4 kPa or less.

Then, the entire surface of the photosensitive resin film was subjected to exposure from the carrier film side at 200 mJ/cm² (wavelength: 365 nm) using a parallel light exposure apparatus (trade name “EXM-1201”, manufactured by ORC MANUFACTURING CO., LTD.) having an ultrahigh pressure mercury lamp as a light source, and, after the exposure, the carrier film was peeled off and removed. A matching liquid was applied to the surface of the cured product of the exposed photosensitive resin film, and the resultant surface was brought into close contact with a prism, and a refractive index of the cured product of the photosensitive resin film on the silicon wafer was measured under the conditions shown below. The conditions for the measurement of a refractive index were as follows.
Measuring apparatus: trade name “Model 2010/M PRISM COUPLER”, manufactured by Metricon Corporation
Wavelength: 632.8 nm
Temperature for measurement: 25° C.
Atmosphere for measurement: Air
Matching liquid: trade name “IMMERSION LIQUID (nD=1.640)”, manufactured by Cargile Laboratories Inc.

### <Evaluation of Resolution>

The via formed in the insulating layer formed in each of Examples was observed using a scanning electron microscope (trade name “SU5000”, manufactured by Hitachi High-Tech Fielding Corporation), and a top diameter and bottom diameter of the via were measured. A taper angle was determined from the top diameter T and bottom diameter B of the via and a thickness X of the insulating layer using the following formula.

$$Taper angle θ ( ° ) = {tan}^{- 1} ( 2 X / ( T - B ) )$$

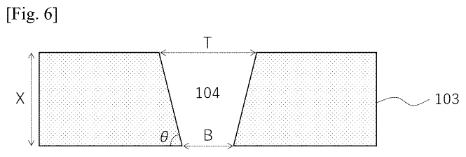

The taper angle is an angle indicated by θ with respect to the via 104 formed in the insulating layer 103 shown in FIG. 6, and, the closer to 90° the taper angle is, the more excellent the resolution.

### Examples 1 to 7 and Comparative Examples 1 and 2

### (1) Production of a Photosensitive Resin Composition

A composition was prepared in accordance with the formulation shown in Table 1 (the unit for the values in the table is “parts by mass”, and, in the case of a solution, is in terms of the amount of the solids), and then kneaded by means of a three-roll mill. Subsequently, methyl ethyl ketone was added to the composition so that the solids content of the resultant mixture became 65% by mass, obtaining a photosensitive resin composition.

### (2) Production of a Photosensitive Resin Film

A polyethylene terephthalate film having a thickness of 25 μm (trade name “HPES0”, manufactured by Toyobo Co., Ltd.) was used as a carrier film. The photosensitive resin composition prepared in each of Examples was applied onto the carrier film so that the resultant dried film had a thickness of 18 μm, and dried at 100° C. for 10 minutes using a hot-air convection dryer to form a photosensitive resin film. Then, a polyethylene film (trade name “NF-13”, manufactured by Tamapoly Co., Ltd.) as a protective film was stacked on the surface of the photosensitive resin film on the side opposite to the surface in contact with the carrier film, producing a photosensitive resin film having a carrier film and a protective film.

### (3) Formation of an Insulating Layer

### (Laminating Step)

While removing the protective film from the “photosensitive resin film having a carrier film and a protective film” produced by the above-mentioned method, the photosensitive resin film was laminated on a copper-clad laminated substrate having a thickness of 1.0 mm using a press-system vacuum laminator (trade name “MVLP-500”, manufactured by Meiki Co., Ltd.) at a pressure-bonding pressure of 0.4 MPa, at a press heating plate temperature of 80° C., for an evacuation time of 25 seconds, for a lamination pressing time of 25 seconds, and under an air pressure of 4 kPa or less, obtaining a laminated material for evaluation.

### (Photo Via Forming Step)

The laminated material for evaluation was subjected to exposure from the carrier film side by means of an i-line stepper (UX-7, manufactured by USHIO INC.) using a step tablet and a mask for via evaluation at the exposure dose (wavelength: 365 nm) shown in Table 1. Then, the carrier film was removed, and then the resultant laminated material was subjected to development using a spraying development machine and using a 1% by mass aqueous solution of sodium carbonate at 30° C. for the development time shown in Table 1, forming a circular via having a diameter of 60 μm when the laminated material for evaluation was viewed as a plane.

TABLE 1

| | | | | | | | | | | | Comparative | |
|---|---|---|---|---|---|---|---|---|---|---|---|---|
| | | | | Example | | | | | | | Example | |
| | | | | 1 | 2 | 3 | 4 | 5 | 6 | 7 | 1 | 2 |
| Formulation | (A) | Photopolymerizable | A1 | 100.0 | | | | | | | 100.0 | |
| of | | compound having | A2 | | 100.0 | 100.0 | 100.0 | 100.0 | 100.0 | 100.0 | | 100.0 |
| photosensitive | | ethylenically | | | | | | | | | | |
| resin | | unsaturated group | | | | | | | | | | |
| composition | | and acidic | | | | | | | | | | |
| (Parts | | substituent | | | | | | | | | | |
| by | (B) | Inorganic filler | B1 | 447.3 | | | | | | | | |
| mass) | | | B2 | | 447.3 | 351.4 | 234.3 | 150.6 | | | | |
| | | | B3 | | | | | | 462.1 | | | |
| | | | B4 | | | | | | | 471.3 | | |
| | | | B5 | | | | | | | | 406.6 | |
| | | | B6 | | | | | | | | | 406.6 |
| | (C) | Thermosetting resin | C1 | 10.4 | 10.4 | 10.4 | 10.4 | 10.4 | 10.4 | 10.4 | 10.4 | 10.4 |
| | | | C2 | 39.0 | 39.0 | 39.0 | 39.0 | 39.0 | 39.0 | 39.0 | 39.0 | 39.0 |
| | (D) | Crosslinking agent | D1 | 22.0 | 22.0 | 22.0 | 22.0 | 22.0 | 22.0 | 22.0 | 22.0 | 22.0 |
| | (E) | Photopolymerization | E1 | 1.9 | 1.9 | 1.9 | 1.9 | 1.9 | 1.9 | 1.9 | 1.9 | 1.9 |
| | | initiator | | | | | | | | | | |
| | (F) | Photosensitizer | F1 | 0.2 | 0.2 | 0.2 | 0.2 | 0.2 | 0.2 | 0.2 | 0.2 | 0.2 |
| | | | F2 | 0.1 | 0.1 | 0.1 | 0.1 | 0.1 | 0.1 | 0.1 | 0.1 | 0.1 |
| | (G) | Coupling agent | G1 | 0.6 | 0.6 | 0.6 | 0.6 | 0.6 | 0.6 | 0.6 | 0.6 | 0.6 |
| | (H) | Pigment | H1 | 1.3 | 1.3 | 1.3 | 1.3 | 1.3 | 1.3 | 1.3 | 1.3 | 1.3 |
| | | | H2 | 0.4 | 0.4 | 0.4 | 0.4 | 0.4 | 0.4 | 0.4 | 0.4 | 0.4 |
| Amount of inorganic filler contained (% by volume) | | | | 56.0 | 56.0 | 50.0 | 40.0 | 30.0 | 56.0 | 56.0 | 56.0 | 56.0 |
| Refractive index of cured product of photosensitive | | | | 1.554 | 1.553 | 1.557 | 1.560 | 1.564 | 1.569 | 1.584 | 1.508 | 1.510 |
| resin film | | | | | | | | | | | | |
| Exposure dose (mJ/cm²) | | | | 190 | 200 | 200 | 200 | 200 | 200 | 200 | 190 | 200 |
| Development time (second) | | | | 40 | 60 | 60 | 60 | 60 | 60 | 60 | 40 | 60 |
| Results of | Resolution | Via diameter | Top | 59.1 | 59.5 | 58.6 | 58.7 | 58.2 | 59.1 | 58.2 | 58.2 | 58.2 |
| evaluation | | φ 60 μm | diameter | | | | | | | | | |
| | | | (μm) | | | | | | | | | |
| | | | Bottom | 54.6 | 55.0 | 54.4 | 57.0 | 57.0 | 55.7 | 52.2 | 48.4 | 41.9 |
| | | | diameter | | | | | | | | | |
| | | | (μm) | | | | | | | | | |
| | | | Taper | 82.9 | 82.9 | 83.3 | 87.3 | 88.1 | 84.6 | 80.5 | 74.8 | 65.6 |
| | | | angle (°) | | | | | | | | | |

The components used shown in Table 1 are as follows.

### [(A) Photopolymerizable Compound Having an Ethylenically Unsaturated Group and an Acidic Substituent]

A1: Acid-modified vinyl group-containing epoxy resin which is obtained by reacting 1,2,3,6-tetrahydrophthalic anhydride with a compound obtained by modifying a cresol novolak epoxy resin with acrylic acid; acid value: 60 mg KOH/g; weight average molecular weight: 6,000 to 7,000
A2: Bisphenol A acid-modified epoxy acrylate (trade name “ZAR-2002H”, manufactured by Nippon Kayaku Co., Ltd.; acid value: 61 mg KOH/g)

### [(B) Inorganic Filler]

B1: Silica-titania particles (volume average particle diameter: 500 nm; refractive index: 1.541; shape: spherical)
B2: Silica-titania particles (volume average particle diameter: 300 nm; refractive index: 1.542; shape: spherical)
B3: Silica-titania particles (volume average particle diameter: 300 nm; refractive index: 1.573; shape: spherical)
B4: Silica-titania particles (volume average particle diameter: 300 nm; refractive index: 1.592; shape: spherical)
B5: Spherical fused silica (volume average particle diameter: 500 nm; refractive index: 1.46; shape: spherical)
B6: Spherical silica particles (volume average particle diameter: 300 nm; refractive index: 1.46; shape: spherical)

### [(C) Thermosetting Resin]

C1: “NC-3000L” (biphenylaralkyl epoxy resin, manufactured by Nippon Kayaku Co., Ltd.; epoxy equivalent: 272 g/eq)
C2: “YX-4000” (biphenyl epoxy resin, manufactured by Mitsubishi Chemical Corporation; epoxy equivalent: 186 g/eq)

### [(D) Crosslinking Agent]

D1: “DPHA” (dipentaerythritol hexaacrylate)

### [(E) Photopolymerization Initiator]

E1: 2-Methyl-4′-methylthio-2-morpholinopropiophene

### [(F) Photosensitizer]

F1: 4,4′-Bis(diethylamino)benzophenone
F2: 2,4-Diethylthioxanthone

### [(G) Coupling Agent]

G1: “KBM-503” (3-methacryloxypropyltrimethoxysilane, manufactured by Shin-Etsu Chemical Co., Ltd.)

### [(H) Pigment]

H1: Blue pigment
H2: Yellow pigment

As apparent from Table 1, the photosensitive resin films in Examples 1 to 7 of the present embodiment have large taper angle and excellent resolution.

### REFERENCE SIGNS LIST

100A: Printed wiring board
101: Substrate
102: Circuit pattern
103: Interlayer insulating layer
104: Via (Via hole)
105: Seed layer
106: Resist pattern
107: Circuit layer of copper
108: Solder resist layer
T: Top diameter of the via
B: Bottom diameter of the via
X: Thickness of the insulating layer

1. A photosensitive resin film comprising (A) a photopolymerizable compound having an ethylenically unsaturated group and an acidic substituent and (B) an inorganic filler,
wherein the amount of the inorganic filler (B) contained is 25% by volume or more, and
wherein the cured product of the photosensitive resin film has a refractive index of 1.550 or more.

2. The photosensitive resin film according to claim 1, wherein the inorganic filler (B) has a refractive index of 1.520 to 1.680.

3. The photosensitive resin film according to claim 1, wherein the inorganic filler (B) is composite particles of silica and a metal oxide other than silica.

4. The photosensitive resin film according to claim 3, wherein the composite particles of silica and a metal oxide other than silica are silica-titania composite particles.

5. The photosensitive resin film according to claim 1 or 2, wherein the inorganic filler (B) is spherical.

6. The photosensitive resin film according to claim 1, further comprising (C) a thermosetting resin.

7. The photosensitive resin film according to claim 1, further comprising (D) a crosslinking agent.

8. The photosensitive resin film according to claim 1, further comprising (E) a photopolymerization initiator.

9. The photosensitive resin film according to claim 1, which is for use in photo via formation.

10. A printed wiring board comprising a cured product of the photosensitive resin film according to claim 1.

11. A semiconductor package comprising the printed wiring board according to claim 10 and a semiconductor element.
